(19) United States
(12) Patent Application Publication
(10) Pub. No.: US 2012/0300381 A1
(43) Pub. Date: Nov. 29, 2012

(54) HINGE DEVICE AND KEYBOARD DOCK AND PORTABLE ELECTRONIC DEVICE HAVING THE SAME

(75) Inventors: Ming-Hua Hung, New Taipei City (TW); Hish-Bin Dai, New Taipei City (TW); Yi-Ling Kuo, New Taipei City (TW); Wen-Chin Wu, New Taipei City (TW); Che-Yuan Chang, New Taipei City (TW)

(73) Assignee: WISTRON CORPORATION, New Taipei City (TW)

(21) Appl. No.: 13/404,006

(22) Filed: Feb. 24, 2012

(30) Foreign Application Priority Data
May 27, 2011 (TW) 100118696

(51) Int. Cl. G06F 1/16; E05D 3/10; E05F 1/12; H05K 7/16

(52) U.S. Cl. 361/679.09; 361/679.01; 16/367; 16/302

(57) ABSTRACT

A hinge device and a keyboard dock and a portable electronic device having the same are provided. The hinge device includes a first body and a second body. The first body is configured to be pivotally connected to a first object. One side of the second body is pivotally connected to the first body, and another side of the second body is configured to be pivotally connected to a second object. The first body rotates around a first axis relative to the first object. The second body rotates around a second axis relative to the first body. The second body rotates around a third axis relative to the second object. The first axis is perpendicular to the second axis, and the second axis is parallel to the third axis.

### CROSS-REFERENCE TO RELATED APPLICATION

This application claims the priority benefit of Taiwan application serial no. 100118696, filed on May 27, 2011. The entirety of the above-mentioned patent application is hereby incorporated by reference herein and made a part of this specification.

### BACKGROUND OF THE INVENTION

1. Field of the Invention

The invention relates to a hinge device, and a keyboard dock and a portable electronic device having the same, and in particular, to a hinge device, and a keyboard dock and a portable electronic device having the same capable of rotating, and opening and closing.

2. Description of Related Art

Conventional tablet computers input control data through a touch screen. However, the operation convenience of the touch screen can not satisfy the needs of all users. Therefore, related external keyboards are used. Conventional external keyboards include a base with a keyboard module, and a support mechanism disposed on the base. Conventional external keyboards use a support mechanism that can pivot relative to the base to support the tablet computer. This is shown in, for example, ROC patent no. 545858, and ROC patent no. 1295705. However, the operation of the aforementioned conventional external keyboards are complicated and the support of the hinge device that is used is unstable. Furthermore, the keyboard modules of conventional external keyboards are directly exposed. Therefore, the keyboard modules are susceptible to damage from contamination such as dust and water. Thus, how to provide a stable supporting hinge device and improve the operation convenience of external keyboards and portable electronic devices is an important topic in the computer industry.

### SUMMARY OF THE INVENTION

The invention is directed to a hinge device that can provide stable and smooth operation of rotating, and opening and closing.

The invention is directed to a keyboard dock having stable and smooth operation of rotating, and opening and closing.

The invention is directed to a portable electronic device, having stable and smooth operation of rotating, and opening and closing.

The hinge device of the invention includes a first body and a second body. The first body is configured to be pivotally connected to a first object. One side of the second body is pivotally connected to the first body, and another side of the second body is configured to be pivotally connected to a second object. The first body rotates around a first axis relative to the first object. The second body rotates around a second axis relative to the first body. The second body rotates around a third axis relative to the second object. The first axis is perpendicular to the second axis. The second axis is parallel to the third axis.

In an embodiment of the invention, the hinge device further includes a pivot element, pivotally connecting the second body and the first body. In addition, the hinge device further includes a torsion spring, disposed on the pivot element, for driving the second body to rotate relative to the first body. Also, the hinge device further includes a damper, disposed between the second body and the first body, for buffering the rotation of the second body relative to the first body driven by the torsion spring.

In an embodiment of the invention, the hinge device includes a pivot element, pivotally connecting the second body and the second object. In addition, the hinge device further includes a torsion spring, disposed on the pivot element, for driving the second body to rotate relative to the second object. Also, the hinge device further includes a damper, disposed between the second body and the second object, for buffering the rotation of the second body relative to the second object driven by the torsion spring.

In an embodiment of the invention, the hinge device further includes a fixing element, for fixing the first object, and configured to be pivotally connected to the first body.

In an embodiment of the invention, the hinge device further includes a fixing element, for fixing the second object, and configured to be pivotally connected to the second body.

In an embodiment of the invention, the hinge device further includes a separation element, fixed to the second body, and pivotally connected to the first body. The separation element rotates around the second axis relative to the first body.

The keyboard dock on the invention includes a base, a support plate, and a hinge device. The base includes a keyboard module. The support plate is for supporting a portable computer. The hinge device includes a first body and a second body. The first body is pivotally connected to the support plate. One side of the second body is pivotally connected to the first body, and another side of the second body is configured to be pivotally connected to the base. The first body rotates around a first axis relative to the support plate. The second body rotates around a second axis relative to the first body. The second body rotates around a third axis relative to the base. The first axis is perpendicular to the second axis. The second axis is parallel to the third axis.

In an embodiment of the invention, the hinge device includes a pivot element, pivotally connecting the second body and the first body. In addition, the hinge device further includes a torsion spring, disposed on the pivot element, for driving the second body to rotate relative to the first body. Also, the hinge device further includes a damper, disposed between the second body and the first body, for buffering the rotation of the second body relative to the first body driven by the torsion spring.

In an embodiment of the invention, the hinge device further includes a pivot element, pivotally connecting the second body and the base. In addition, the hinge device further includes a torsion spring, disposed on the pivot element, for driving the second body to rotate relative to the base. Also, the hinge device further includes a damper, disposed between the second body and the base, for buffering the rotation of the second body relative to the base driven by the torsion spring.

In an embodiment of the invention, the hinge device further includes a fixing element, for fixing the support plate, and configured to be pivotally connected to the first body.

In an embodiment of the invention, the hinge device further includes a fixing element, for fixing the base, and configured to be pivotally connected to the second body.

In an embodiment of the invention, the hinge device further includes a separation element, fixed to the second body, and pivotally connected to the first body. The separation element rotates around the second axis relative to the first body.

In an embodiment of the invention, the keyboard dock further includes a latch, disposed in the base, for locking the support plate and limiting the rotation of the second body relative to the base.

In an embodiment of the invention, the keyboard dock further includes a first magnetic element and a second magnetic element. The first magnetic element is disposed in the edge of the support plate, the second magnetic element is disposed in the edge of the base, and when the support plate and the base overlap, the first magnetic element magnetically attracts the second magnetic element.

In an embodiment of the invention, the keyboard dock further includes a first magnetic element and a second magnetic element. The first magnetic element is disposed in the edge of the support plate, and the second magnetic element is disposed in the base. When the support plate is tilted relative to the base and exposes the keyboard module, the first magnetic element magnetically attracts the second magnetic element. In addition, the keyboard dock further includes a third magnetic element. The third magnetic element is disposed in the edge of the base. When the support plate and the base overlap, the first magnetic element magnetically attracts the third magnetic element.

In an embodiment of the invention, the keyboard dock further includes a pin set, disposed beside the keyboard module of the base, and electrically connected to the keyboard module. When the support plate tilts relative to the base and exposes the keyboard module, the pin set is configured to electrically connect the portable computer on the support plate.

The portable electronic device of the invention includes a host, a display unit, and a hinge device. The display unit is electrically connected to the host. The hinge device includes a first body and a second body. The first body is pivotally connected to the display unit. One side of the second body is pivotally connected to the first body, and another side of the second body is configured to be pivotally connected to the host. The first body rotates around a first axis relative to the display unit. The second body rotates around a second axis relative to the first body. The second body rotates around a third axis relative to the host. The first axis is perpendicular to the second axis. The second axis is parallel to the third axis.

In an embodiment of the invention, the hinge device includes a pivot element, pivotally connecting the second body and the first body. In addition, the hinge device further includes a torsion spring, disposed on the pivot element, for driving the second body to rotate relative to the first body. Also, the hinge device further includes a damper, disposed between the second body and the first body, for buffering the rotation of the second body relative to the first body driven by the torsion spring.

In an embodiment of the invention, the hinge device further includes a pivot element, pivotally connecting the second body and the host. In addition, the hinge device further includes a torsion spring, disposed on the pivot element, for driving the second body to rotate relative to the host. Also, the hinge device further includes a damper, disposed between the second body and the host, for buffering the rotation of the second body relative to the host driven by the torsion spring.

In an embodiment of the invention, the hinge device further includes a fixing element, for fixing the display unit, and configured to be pivotally connected to the first body.

In an embodiment of the invention, the hinge device further includes a fixing element, for fixing the base, and configured to be pivotally connected to the second body.

In an embodiment of the invention, the hinge device further includes a separation element, fixed to the second body, and pivotally connected to the first body. The separation element rotates around the second axis relative to the first body.

In an embodiment of the invention, the portable electronic device further includes a latch, disposed in the host, for locking the display unit and limiting the rotation of the second body relative to the host.

In an embodiment of the invention, the portable electronic device further includes a first magnetic element and a second magnetic element. The first magnetic element is disposed in the edge of the display unit, and the second magnetic element is disposed in the edge of the host. When the display unit and the host overlap, the first magnetic element magnetically attracts the second magnetic element.

In an embodiment of the invention, the portable electronic device further includes a first magnetic element and a second magnetic element. The first magnetic element is disposed in the edge of the display unit, and the second magnetic element is disposed in the host. When the display unit tilts relative to the host, the first magnetic element magnetically attracts the second magnetic element. The portable electronic device further includes a third magnetic element. The third magnetic element is disposed in the edge of the host. When the display unit and the host overlap, the first magnetic element magnetically attracts the third magnetic element.

To sum up, the hinge device, the keyboard dock, and the portable electronic device of the invention provide rotation around three axes, to allow the user of the keyboard dock and the portable electronic device to experience a convenient operating mode.

In order to make the aforementioned and other features and advantages of the invention more comprehensible, embodiments accompanying figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1 shows a perspective view of a keyboard dock according to an embodiment of the invention.

FIG. 2 shows an exploded view of a hinge device of an embodiment of the invention applied in the keyboard dock of FIG. 1.

FIG. 3A and FIG. 3B are three-dimensional views at two different perspectives of the keyboard dock of FIG. 1 under another state.

FIG. 4 is a three-dimensional view showing when a support plate of the keyboard dock of FIG. 1 is rotating.

FIG. 5 is a three-dimensional view showing when a support plate of the keyboard dock of FIG. 1 is done rotating.

FIG. 6 is another perspective view of the keyboard dock of FIG. 1.

FIG. 7 is a schematic view of a portable electronic device according to an embodiment of the invention.

### DESCRIPTION OF EMBODIMENTS

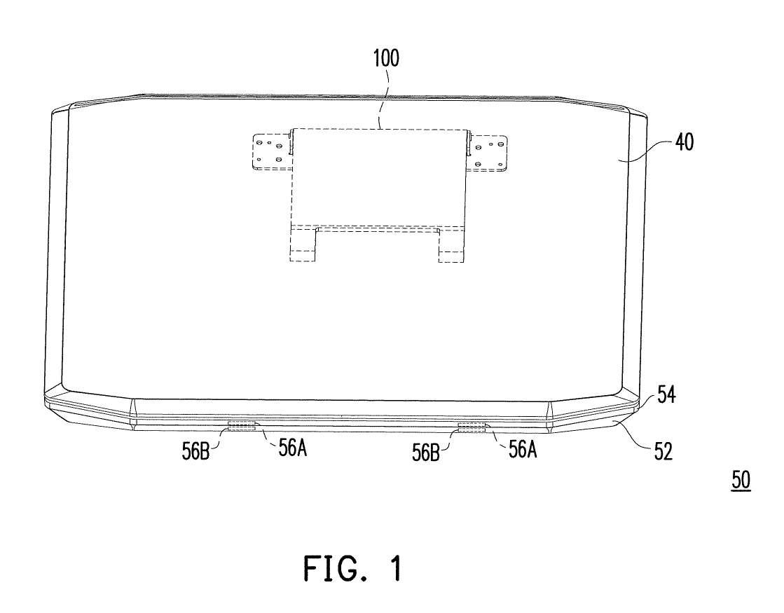

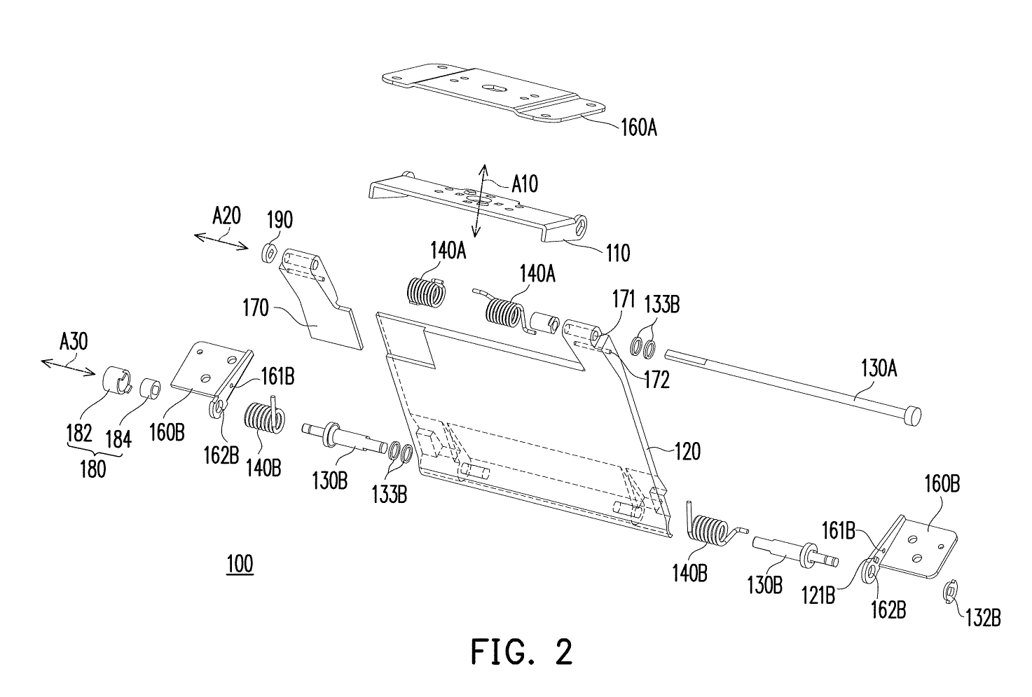

FIG. 1 shows a perspective view of a keyboard dock according to an embodiment of the invention. FIG. 2 shows an exploded view of a hinge device of an embodiment of the invention applied in the keyboard dock of FIG. 1.

Referring to FIG. 1 and FIG. 2, the keyboard dock 50 of the embodiment includes a base 52, a support plate 54, and a hinge device 100. The support plate 54 is for supporting a portable computer 40. The hinge device 100 includes a first body 110 and a second body 120. The first body 110 is pivotally connected to the support plate 54. One side of the second body 120 is pivotally connected to the first body 110, and another side of the second body 120 is configured to be pivotally connected to the base 52. The first body 110 rotates around a first axis A10 relative to the support plate 54. The second body 120 rotates around a second axis A20 relative to the first body 110. The second body 120 rotates around a third axis A30 relative to the base 52. The first axis A10 is perpendicular to the second axis A20. The second axis A20 is parallel to the third axis A30.

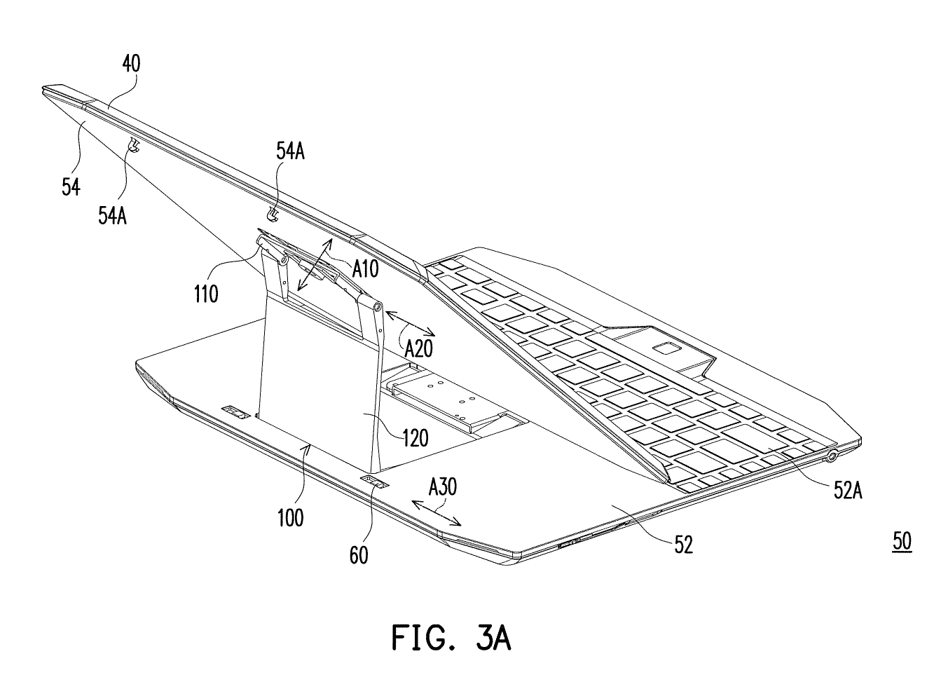

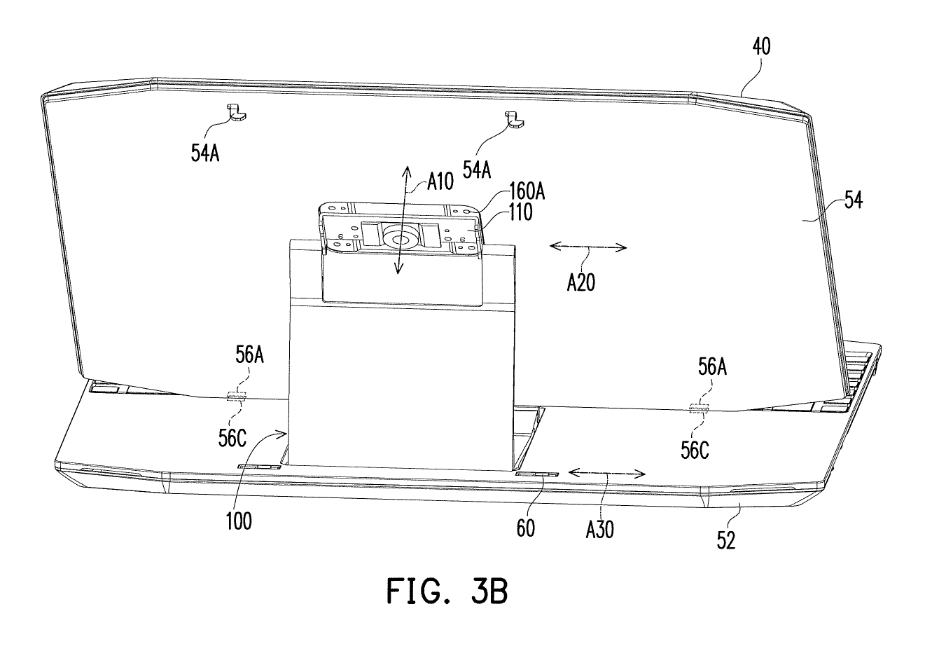

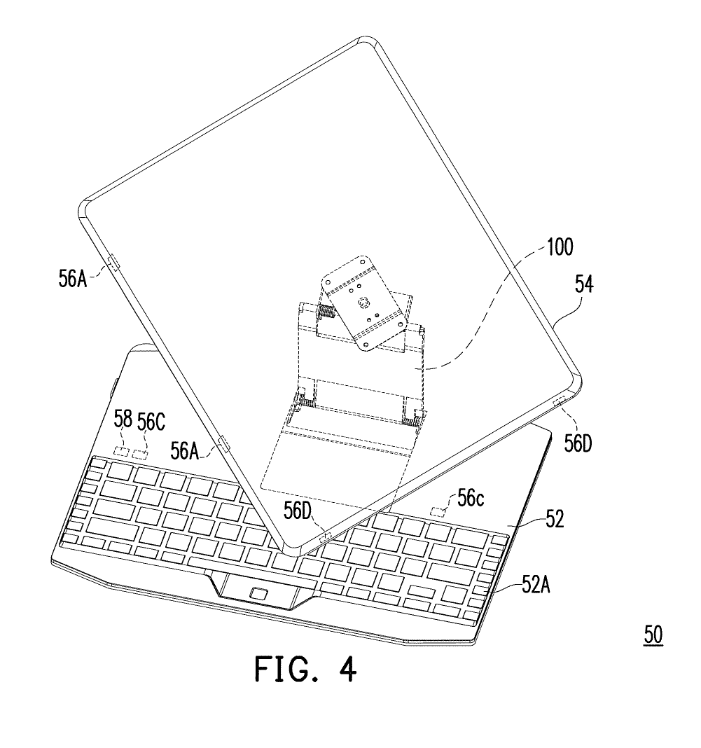

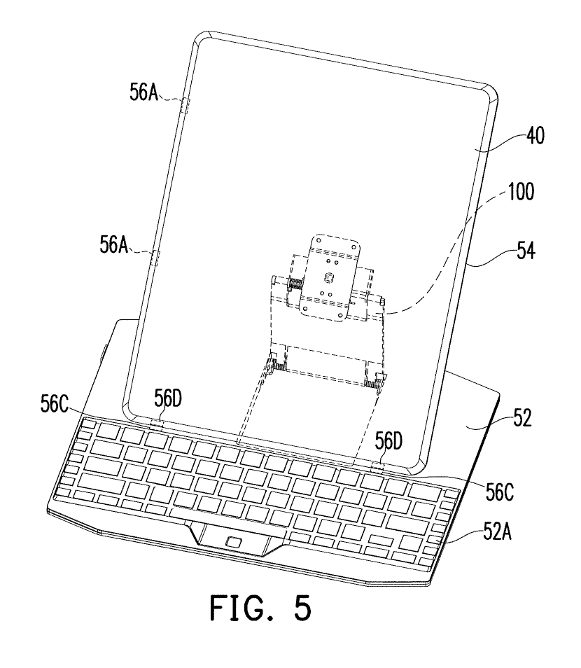

Through the hinge device 100, the support plate 54 can be flipped up from the base 52 and tilted relative to the base 52 (shown in FIG. 3A). In addition, the support plate 54 can rotate relative to the first body 110 of the hinge device 100 (shown in FIG. 4). Finally, the support plate 54 can be rotated 90 degrees to the state shown in FIG. 5, and the support plate 54 is tilted relative to the base 52 (shown in FIG. 5). When the support plate 54 is flipped and tilted relative to the base 52 (as shown in FIG. 3A and FIG. 5), a keyboard module 52A of the base 52 is exposed. In this state, the portable computer 40 can be disposed on the support plate 54, so the user can view the display of the portable computer 40 for a suitable angle. In addition, the keyboard module 52A and the portable computer 40 can selectively have a wired or wireless connection. The user can input signals to the portable computer 40 from the keyboard module 52A, and control the portable computer 40.

Referring to FIG. 2, the hinge device 100 of the embodiment further includes a pivot element 130A, pivotally connecting the second body 120 and the first body 110. For example, the pivot element 130A passes through the second body 120 and the first body 110. Thus, the second body 120 and the first body 110 can rotate around the pivot element 130A.

The hinge device 100 of the embodiment further includes a separation element 170, fixed to the second body 120, and pivotally connected to the first body 110. The separation element 170 and the second body 120 mutually rotate around the second axis A20 relative to the first body 110. The design of the separation element 170 is for convenience in assembly. In other embodiments, the separation element 170 can be integrally formed with the second body 120.

In a preferred embodiment, the first body 110 and a end of the pivot element 130A are fixed to each other, and the second body 120 is pivotally connected to the pivot element 130A through an opening 171 of the separation element 170. In addition, the hinge device 100 further includes a torsion spring 140A, disposed on the pivot element 130A, for driving the second body 120 to rotate relative to the first body 110. In further detail, after the torsion spring 140A is disposed on the pivot element 130A, an end of the torsion spring 140A is fixed to a fixing hole 172 of the separation element 170 of the second body 120, and the other end of the torsion spring 140A is fixed to the first body 110. In addition, the pivot element 130A and the second body 120 can be designed with suitable angle limitations. For example, a limit element 190 is combined to an end of the pivot element 130A, and synchronously rotates with the pivot element 130A. The limit element 190 is not circular, but has an angle. When the first body 110 rotates, it drives the pivot element 130A and the limit element 190 to rotate. But when rotated to a certain angle, two sides of the angle on the limit element 190 will press against the separation element 170 and stop the first body 110 from further rotation. Thus, when the second body 120 and the first body 110 receive a force from the torsion spring 140A and correspondingly open to a specific suitable view angle, the pivot element 130A and the second body 120 can prevent the first body 110 from opening too far relative to the second body 120 through the limitation element 190.

Referring to FIG. 2 and FIG. 3B, the hinge device 100 of the embodiment further includes a pivot element 130B, pivotally connecting the second body 120 and the base 52. In a preferred embodiment of the invention, the hinge device 100 further includes a fixing element 160B, for fixing the base 52, and configured to be pivotally connected to the second body 120. That is to say, an end of the pivot element 130B is fixed to the second body 120, and the other end is disposed on an opening 162B of the fixing element 160B. Furthermore, the hinge device 100 further includes a torsion spring 140B, disposed on the pivot element 130B, for driving the second body 120 to rotate relative to the base 52. In detail, a locking element 132B is disposed on the pivot element 130B, and a locking part 121B is disposed on the fixing element 160B. An end of the torsion spring 140B is fixed to a hole 161B of the fixing element 160B, and the other end of the torsion spring 140B is fixed to the second body 120. Thus, when the second body 120 and the fixing element 160B are parallely overlapped, the torsion spring 140B will receive a force and be in a compressed state. The torsion spring 140B simultaneously gives force to the second body 120 and the fixing element 160B, wanting the two to open. Since the fixing element 160B is fixed to the base 52 and does not move, the torsion spring 140B gives off force to the second body 120, lifting the second body 120. When used with the torsion spring 140B, the support plate 54 automatically props up to a suitable viewing angle. Next, the locking element 132B of the pivot element 130B and the locking part 121B of the fixing element 160B press against each other, limiting the angle of rotation of the second body 120 relative to the fixing element 160B, preventing the second body 120 from opening too far relative to the fixing element 160B.

Also, in the embodiment, the hinge device 100 further includes a damper 180, disposed between the second body 120 and the fixing element 160B fixed to the base 52. The damper 180 is for buffering the speed of the rotation of the second body 120 relative to the fixing element 160B when receiving the force released from the torsion spring 140B. For example, the damper 180 includes a first element 182 and a second element 184. The first element 182 is combined with the fixing element 160B, and moves with the fixing element 160B. The second element 184 is combined with the pivot element 130B, and moves with the pivot element 130B. At the same time, the second element 184 is disposed in the first element 182, and the second element 184 can rotate relative to the first element 182. When the second body 120 receives a force from the torsion spring 140B and rotates and lifts relative to the fixing element 160B, the friction between the second element 184 and the first element 182 will slow down the speed of rotation of the second body 120 relative to the base 52. In order to increase smoothness and reduce friction in movement, lubricant may be applied between the second element 184 and the first element 182.

In addition, a plurality of friction pads 133B may be disposed on the pivot element 130B, to buffer the speed of the rotation of the second body 120 relative to the fixing element 160B when receiving the force released from the torsion spring 140B. Similarly, the friction pads 133B can be used and disposed in the pivot element 130A, to buffer the speed of the rotation of the first body 110 relative to the second body 120 when receiving the force released from the torsion spring 140A. The use of the damper 180 and the friction pads 133B or other hinge devices that use similar damping effects or buffer effects on uneven contours are known to those skilled in the art, and will not be repeated hereafter.

The hinge device 100 of the embodiment further includes a fixing element 160A, for fixing the support plate 54, and is configured to be pivotally connected to the first body 110. The fixing element 160B is then used to fix to the base 52, and used to pivotally connect the second body 120. The fixing element 160A and the fixing element 160B are provided where the first body 110 and the second body 120 require pivoting. However, the fixing element 160A can be integrally formed with the support plate 54, and the fixing element 160B can be integrally formed with the base 52.

Referring to FIG. 1 and FIG. 3B, the keyboard dock 50 of the embodiment further includes at least a magnetic element 56A, at least a magnetic element 56B, and at least a magnetic element 56C. The magnetic element 56A is disposed in the edge of the support plate 54, the magnetic element 56B is disposed in the edge of the base 52, and the magnetic element 56C is disposed in the edge of the keyboard module 52A of the base 52 (referenced in FIG. 3A). As seen in the state of FIG. 1, when the support plate 54 and the base 52 overlap, the magnetic element 56A magnetically attracts the magnetic element 56B. Thus, the magnetic attraction is used to maintain the state of the support plate 54 and the base 52 overlapping. As seen in the state of FIG. 3B, when the support plate 54 tilts relative to the base 52, the magnetic element 56A magnetically attracts the magnetic element 56C. Thus, the magnetic attraction is used to maintain the state of the support plate 54 tilting relative to the base 52. Thus, when the user touches portable computer 40 on the support plate 54, the support plate 54 can stably support the portable computer 40 so that it does not flip.

To switch the support plate 54 from a state of overlapping with the base 52 to tilting relative to the base 52, the user exerts a force so the support plate 54 is slightly lifted, removing the magnetic attraction between the magnetic element 56A and the magnetic element 56B. Next, the torsion spring 140B will cause the second body 120 to flip up from the base 52. At the same time, the torsion spring 140A will cause the first body 110 to flip relative to the second body 120, so that in the configuration of the support plate 54, a side of the magnetic element 56A tries to stay in contact with the base 52 and is tilted relative to the base. When the above action stops, the magnetic element 56A magnetically attracts the magnetic element 56C, as seen in FIG. 3B. In other words, in the process of the keyboard dock 50 of the embodiment changing from the state in FIG. 1 to the state in FIG. 3B, the goal of automatic movement is achieved through the torsion springs 140A and 140B. Of course, the torsion springs 140A and 140B may not be disposed, and the above movements may be done manually by the user.

The keyboard dock 50 of the embodiment further includes a pin set 58 (shown in FIG. 4 and FIG. 5), disposed beside the keyboard module 52A of the base 52 and electrically connected to the keyboard module 52A. The pin set 58 can be a pogo pin set. When the support plate 54 tilts relative to the base 52 and exposes the keyboard module 52A (as shown in FIG. 3A and FIG. 3B), the pin set 58 is configured to electrically connect the portable computer 40 on the support plate 54. In other words, the signal the user inputs from the keyboard module 52A can be transmitted to the portable computer 40 through the pin set 58. In addition, the pin set 58 has, for example, a magnet (not shown), to magnetically attract the portable computer 40 on the support plate 54 during the state shown in FIG. 3A. A corresponding magnet (not shown) can also be disposed on the portable computer 40, to strengthen the attraction between the pin set 58 and the portable computer 40.

When the support plate 54 is tilted relative to the base 52, the user can exert a force so the support plate 54 is slightly lifted, removing the magnetic attraction between the magnetic element 56A and the magnetic element 56C. Next, the support plate 54 is rotated to turn relative to the first body 110, as shown in FIG. 4. After the support plate 54 is rotated 90 degrees, the support plate 54 is tilted relative to the base 52, as shown in FIG. 5. With this design, the user can rotate the support plate 54 according to the desired direction of the display image of the portable computer 40, so that the direction of the display image of the portable computer 40 is the same as the direction of the keyboard module 52A of the base 52. The keyboard module 50 of the embodiment can further include at least one magnetic element 56D, disposed in the edge of the support plate 54. As seen in the state of FIG. 5, when the support plate 54 and the base 52 overlap, the magnetic element 56D magnetically attracts the magnetic element 56C. The mentioned magnetic elements 56A to 56D can be a permanent magnet, an electromagnet, or a metal-like material that can be magnetically attracted.

Furthermore, as seen in the states of FIG. 3B and FIG. 5, the support plate 54 tilts towards the center of the base 52, and the angles the support plate 54 tilts relative to the base 52 are the same. In order to satisfy the above requirements, a suitable pivot area between the support plate 54 and the first body 110 must be selected.

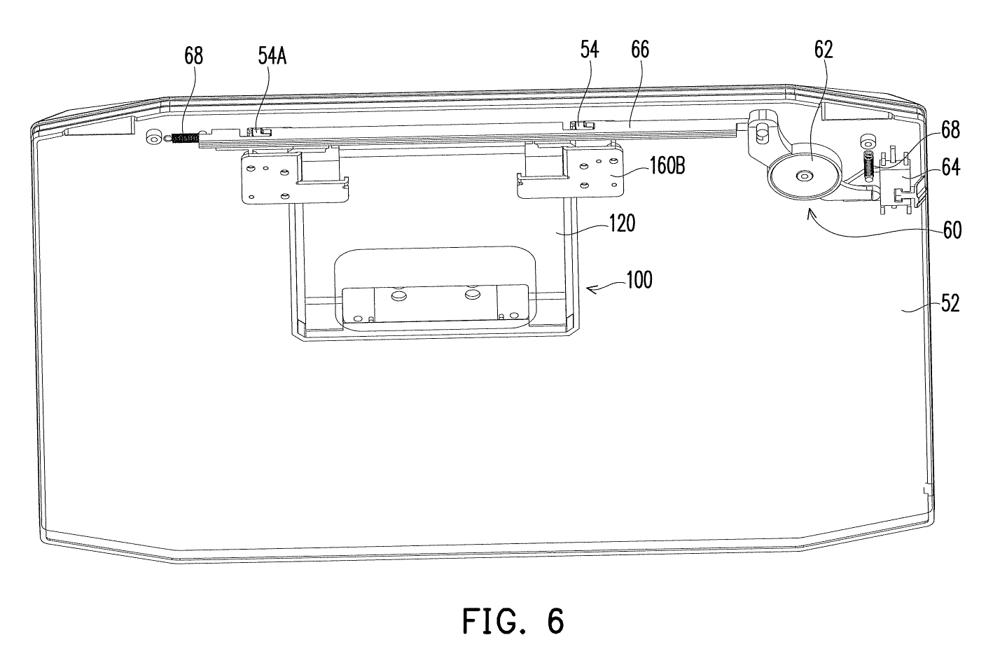

FIG. 6 is another perspective view of the keyboard dock of FIG. 1. Referring to FIG. 6, the keyboard dock 50 further includes a latch 60, disposed in the base 52, for locking the support plate 54 and limiting the rotation of the second body 120 relative to the base 52. When the latch 60 is hooked to the support plate 54, the state of the support plate 54 and the base 52 overlapping is maintained. When the latch 60 is not hooked to the support plate 54, the support plate 54 can be flipped up to tilt relative to the base 52 manually through the user or automatically through the hinge device 100. In FIG. 6, the base 52 is transparent, to show the latch 60. The latch 60 of the embodiment includes a turntable 62, a sliding element 64, a locking part 66, and two tensile springs 68. The turntable 62 is pivotally disposed in the base 52, and can rotate relative to the base 52. The sliding element 64 is slidably disposed in the base 52, and is connected to the turntable 62. A portion of the sliding element 64 is located outside the base 52, allowing the user to push the sliding element 64. The locking part 66 is slidably disposed in the base 52, and is connected to the turntable 62. In the embodiment, the sliding directions of the sliding element 64 and the locking part 66 are perpendicular to each other. When the user slides the sliding element 64, the sliding element 64 drives the turntable 62 to rotate. The turntable 62 then drives the locking part 66 to slide, so that the locking part 66 locks with at least a hook 54A or separates with the hook 54A of the support plate.

A tensile spring 68 is disposed between the sliding element 64 and the base 52, and the other tensile spring 68 is disposed between the locking part 66 and the base 52. The tensile spring 68 causes the locking part 66 to maintain in a suitable position locking the hook 54A. When the user slides the sliding element 64 causing the locking part 66 and the hook 54A to separate, the tensile spring 68 causes the locking part 66 to return to a suitable position in locking the hook 54A, and the tensile spring 68 also causes the sliding element 64 to return to the position it was in before the user caused it to slide. When the support plate again overlaps with the base 52, the hook 54A will push the locking part 66, and the tensile spring 68 then causes the locking part 66 to return to the original position and lock the hook 54A. Of course, the latch 60 is not limited to the aforementioned component structure. Persons having ordinary skills in the art know that the latch 60 has many different designs and variations.

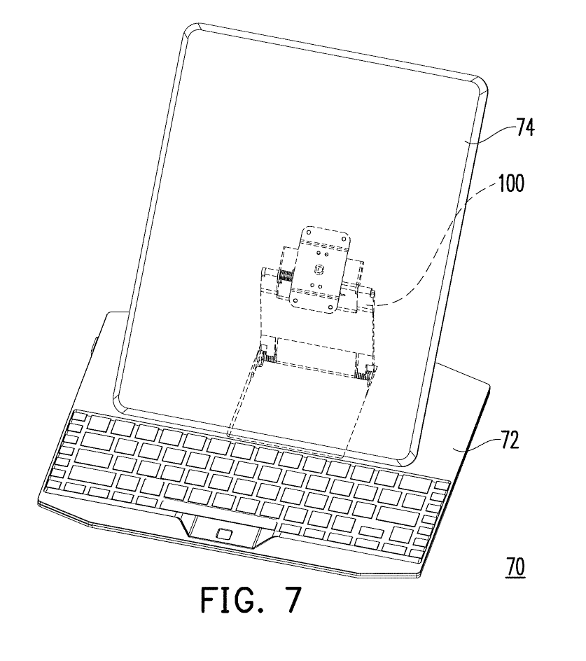

FIG. 7 is a schematic view of a portable electronic device according to an embodiment of the invention. Referring to FIG. 7, the portable electronic device 70 of the embodiment includes a host 72, a display unit 74, and a hinge device 100 similar to the one in FIG. 2. The display unit 74 is electrically connected to the host 72. The host 72 includes most of the components required to operate the portable electronic device 70, and the display unit 74 is mainly used for display functions. The second body 120 referenced in FIG. 2 is pivotally connected to the host 72. The first body 110 referenced in FIG. 2 is pivotally connected to the display unit 74. For the details of the hinge device 100, please refer to the aforementioned embodiments. The latch 60 of FIG. 6 can be applied to the portable electronic device 70 of the embodiment.

To sum up, the hinge device, the keyboard dock, and the portable electronic device of the invention provide freedom in rotation and flipping, and greatly improves the convenience in operation of the keyboard dock and the portable electronic device.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A hinge device, comprising:
a first body, configured to be pivotally connected to a first object; and
a second body, wherein one side of the second body is pivotally connected to the first body, and another side of the second body is configured to be pivotally connected to a second object, the first body rotates around a first axis relative to the first object, the second body rotates around a second axis relative to the first body, the second body rotates around a third axis relative to the second object, the first axis is perpendicular to the second axis, and the second axis is parallel to the third axis.

2. The hinge device as claimed in claim 1, further comprising a pivot element, pivotally connecting the second body and the first body.

3. The hinge device as claimed in claim 2, further comprising a torsion spring, disposed on the pivot element, for driving the second body to rotate relative to the first body.

4. The hinge device as claimed in claim 3, further comprising a damper, disposed between the second body and the first body, for buffering the rotation of the second body relative to the first body driven by the torsion spring.

5. The hinge device as claimed in claim 1, further comprising a pivot element, pivotally connecting the second body and the second object.

6. The hinge device as claimed in claim 5, further comprising a torsion spring, disposed on the pivot element, for driving the second body to rotate relative to the second object.

7. The hinge device as claimed in claim 6, further comprising a damper, disposed between the second body and the second object, for buffering the rotation of the second body relative to the second object driven by the torsion spring.

8. The hinge device as claimed in claim 1, further comprising a fixing element, for fixing the first object, and configured to be pivotally connected to the first body.

9. The hinge device as claimed in claim 1, further comprising a fixing element, for fixing the second object, and configured to be pivotally connected to the second body.

10. The hinge device as claimed in claim 1, further comprising a separation element, fixed to the second body, and pivotally connected to the first body, the separation element rotates around the second axis relative to the first body.

11. A keyboard dock, comprising:
a base, having a keyboard module;
a support plate, for supporting a portable computer; and
a hinge device, comprising:
a first body, pivotally connected to the support plate; and
a second body, wherein one side of the second body is pivotally connected to the first body, and another side of the second body is configured to be pivotally connected to the base, the first body rotates around a first axis relative to the support plate, the second body rotates around a second axis relative to the first body, the second body rotates around a third axis relative to the base, the first axis is perpendicular to the second axis, and the second axis is parallel to the third axis.

12. The keyboard dock as claimed in claim 11, wherein the hinge device further comprises a pivot element, pivotally connecting the second body and the first body.

13. The keyboard dock as claimed in claim 12, wherein the hinge device further comprises a torsion spring, disposed on the pivot element, for driving the second body to rotate relative to the first body.

14. The keyboard dock as claimed in claim 13, wherein the hinge device further comprises a damper, disposed between the second body and the first body, for buffering the rotation of the second body relative to the first body driven by the torsion spring.

15. The keyboard dock as claimed in claim 11, wherein the hinge device further comprises a pivot element, pivotally connecting the second body and the base.

16. The keyboard dock as claimed in claim 15, wherein the hinge device further comprises a torsion spring, disposed on the pivot element, for driving the second body to rotate relative to the base.

17. The keyboard dock as claimed in claim 16, wherein the hinge device further comprises a damper, disposed between the second body and the base, for buffering the rotation of the second body relative to the base driven by the torsion spring.

18. The keyboard dock as claimed in claim 11, wherein the hinge device further comprises a fixing element, for fixing the support plate, and configured to be pivotally connected to the first body.

19. The keyboard dock as claimed in claim 11, wherein the hinge device further comprises a fixing element, for fixing the base, and configured to be pivotally connected to the second body.

20. The keyboard dock as claimed in claim 11, wherein the hinge device further comprises a separation element, fixed to the second body, and pivotally connected to the first body, the separation element rotates around the second axis relative to the first body.

21. The keyboard dock as claimed in claim 11, further comprising a latch, disposed in the base, for locking the support plate and limiting the rotation of the second body relative to the base.

22. The keyboard dock as claimed in claim 11, further comprising a first magnetic element and a second magnetic element, wherein the first magnetic element is disposed in the edge of the support plate, the second magnetic element is disposed in the edge of the base, and when the support plate and the base overlap, the first magnetic element magnetically attracts the second magnetic element.

23. The keyboard dock as claimed in claim 11, further comprising a first magnetic element and a second magnetic element, wherein the first magnetic element is disposed in the edge of the support plate, the second magnetic element is disposed in the base, and when the support plate is tilted relative to the base and exposes the keyboard module, the first magnetic element magnetically attracts the second magnetic element.

24. The keyboard dock as claimed in claim 23, further comprising a third magnetic element, wherein the third magnetic element is disposed in the edge of the base, and when the support plate and the base overlap, the first magnetic element magnetically attracts the third magnetic element.

25. The keyboard dock as claimed in claim 11, further comprising a pin set, disposed beside the keyboard module of the base, and electrically connected to the keyboard module, wherein when the support plate tilts relative to the base and exposes the keyboard module, the pin set is configured to electrically connect the portable computer on the support plate.

26. A portable electronic device, comprising:
a host;
a display unit, electrically connected to the host; and
a hinge device, comprising:
a first body, pivotally connected to the display unit; and
a second body, wherein one side of the second body is pivotally connected to the first body, and another side of the second body is pivotally connected to the host, the first body rotates around a first axis relative to the display unit, the second body rotates around a second axis relative to the first body, the second body rotates around a third axis relative to the host, the first axis is perpendicular to the second axis, and the second axis is parallel to the third axis.

27. The portable electronic device as claimed in claim 26, wherein the hinge device further comprises a pivot element, pivotally connecting the second body and the first body.

28. The portable electronic device as claimed in claim 27, wherein the hinge device further comprises a torsion spring, disposed on the pivot element, for driving the second body to rotate relative to the first body.

29. The portable electronic device as claimed in claim 28, wherein the hinge device further comprises a damper, disposed between the second body and the first body, for buffering the rotation of the second body relative to the first body driven by the torsion spring.

30. The portable electronic device as claimed in claim 26, wherein the hinge device further comprises a pivot element, pivotally connecting the second body and the host.

31. The portable electronic device as claimed in claim 30, wherein the hinge device further comprises a torsion spring, disposed on the pivot element, for driving the second body to rotate relative to the host.

32. The portable electronic device as claimed in claim 31, wherein the hinge device further comprises a damper, disposed between the second body and the host, for buffering the rotation of the second body relative to the host driven by the torsion spring.

33. The portable electronic device as claimed in claim 26, wherein the hinge device further comprises a fixing element, for fixing the display unit, and configured to be pivotally connected to the first body.

34. The portable electronic device as claimed in claim 26, wherein the hinge device further comprises a fixing element, for fixing the host, and configured to be pivotally connected to the second body.

35. The portable electronic device as claimed in claim 26, wherein the hinge device further comprises a separation element, fixed to the second body, and pivotally connected to the first body, the separation element rotates around the second axis relative to the first body.

36. The portable electronic device as claimed in claim 26, further comprising a latch, disposed in the host, for locking the display unit and limiting the rotation of the second body relative to the host.

37. The portable electronic device as claimed in claim 26, further comprising a first magnetic element and a second magnetic element, wherein the first magnetic element is disposed in the edge of the display unit, the second magnetic element is disposed in the edge of the host, and when the display unit and the host overlap, the first magnetic element magnetically attracts the second magnetic element.

38. The portable electronic device as claimed in claim 26, further comprising a first magnetic element and a second magnetic element, wherein the first magnetic element is disposed in the edge of the display unit, the second magnetic element is disposed in the host, and when the display unit is tilted relative to the host, the first magnetic element magnetically attracts the second magnetic element.

39. The portable electronic device as claimed in claim 38, further comprising a third magnetic element, wherein the third magnetic element is disposed in the edge of the host, and when the display unit and the host overlap, the first magnetic element magnetically attracts the third magnetic element.
